(19) United States
(12) Patent Application Publication
(10) Pub. No.: US 2019/0115509 A1
(43) Pub. Date: Apr. 18, 2019

(54) LIGHT-EMITTING DEVICE

(71) Applicant: LG INNOTEK CO., LTD., Seoul (KR)

(72) Inventors: Sang Youl LEE, Seoul (KR); Chung Song KIM, Seoul (KR); Ji Hyung MOON, Seoul (KR); Sun Woo PARK, Seoul (KR)

(73) Assignee: LG INNOTEK CO., LTD., Seoul (KR)

(21) Appl. No.: 16/089,944

(22) PCT Filed: Mar. 29, 2017
(86) PCT No.: PCT/KR2017/003383

§ 371 Date: Sep. 28, 2018

(30) Foreign Application Priority Data
Mar. 30, 2016 (KR) 10-2016-0038351

(51) Int. Cl. H01L 33/62; H01L 33/40; H01L 33/50; H01L 33/32; F21V 8/00; G02F 1/1335

(52) U.S. Cl. CPC H01L 33/62; H01L 33/405; G02F 1/133603; H01L 33/32; G02B 6/0073; H01L 33/50

(57) ABSTRACT

One embodiment relates to a light-emitting device, a backlight unit and a lighting device. The light-emitting device of the embodiment includes a light-emitting structure and a phosphor layer disposed on the light-emitting structure. The first and second pads are electrically connected with the light-emitting structure, wherein the phosphor layer is disposed on one side of the light-emitting device, and the first and second pads are disposed on the lower part of the light-emitting device. Thus a side view-type light-emitting device having a simplified structure can be enabled. Thus, the embodiment can enable thinning and slimming by means of the simplified structure.

### TECHNICAL FIELD

An embodiment relates to a light emitting device, a light emitting unit and a lighting apparatus.

### BACKGROUND ART

A light emitting diode (LED) is one of light emitting devices that emit light when a current is applied. The light emitting diode can emit light with high efficiency at a low voltage, thus provide excellent energy saving effect.

In recent years, the problem of luminance of a light emitting diode has been greatly resolved, and it has been applied to various devices such as a backlight unit of a liquid crystal display device, a display board, a display device, and a home appliance.

According to this trend, a light emitting diode is required to have a structure capable of improving light efficiency and thinning and slimming so that it can be applied to various applications.

### DISCLOSURE

### [Technical Problem]

The embodiment is intended to provide a light emitting device, a light emitting unit and a lighting device capable of implementing thinning.

Embodiments is intended to provide a light emitting device, a light emitting unit, and a lighting device capable of implementing slimming of a side view light emitting device.

Embodiments provide a light emitting device, a light emitting unit, and a lighting device capable of improving light efficiency.

In addition, the embodiment is intended to provide a light emitting device, a light emitting unit and a manufacturing method which can simplify the manufacturing process.

Also, the embodiment is intended to provide a light emitting unit capable of improving the light incident efficiency.

In addition, the embodiment is intended to provide a light emitting unit and a lighting device of high luminance by improving the light-incident efficiency of the light guide plate.

### [Technical Solution]

The light emitting device of the embodiment comprises a light emitting structure, a phosphor layer disposed on the light emitting structure, and first and second pads electrically connected to the light emitting structure, wherein the phosphor layer is disposed on one side of the light emitting device, The two pads may be disposed under the light emitting device. Accordingly, the embodiment can implement a side view type light emitting device having a simplified structure. Therefore, the embodiment can implement thinning and slimming by a simplified structure.

In addition, the embodiment improves the light-incident efficiency of the light guide plate, thereby implementing a light emitting unit of high brightness.

The lighting device of the embodiment may comprise the light emitting device package to improve the light efficiency.

### [Advantageous Effects]

Embodiments comprise a first and second pads disposed at a lower portion of a light emitting device, and an output portion disposed at one side of the light emitting device, and a phosphor layer is disposed at the emitting portion to implement a side view type light emitting device having a simplified structure.

The light emitting device of the first embodiment can be made thinner and slimmer than a general light emitting device package having a connection structure of a light emitting chip and a lead frame by a simplified structure.

The light emitting device of the first embodiment can improve the light efficiency by resolving the light loss by the simplified structure.

In the light emitting unit of the embodiment, light emitting devices having a simplified structure are disposed, thereby implementing thinning and slimming. In addition, the light emitting unit of the embodiment can improve the light efficiency of light incident on the light guide plate by resolving the light loss by the light emitting device having a simplified structure. That is, the embodiment improves the light-incident efficiency of the light guide plate, thereby implementing a light emitting unit of high brightness.

### DESCRIPTION OF DRAWINGS

FIG. 1 is a perspective view illustrating a light emitting device according to a first embodiment.

FIG. 2 is a cross-sectional view illustrating a light emitting device taken along a line I-I′ in FIG. 1.

FIG. 3 is a perspective view illustrating a bottom portion of the light emitting device according to a first embodiment.

FIGS. 4 to 15 are a plan view and a cross-sectional view illustrating a manufacturing step of the light emitting device according to the first embodiment.

FIGS. 16 to 27 are a plan view and a cross-sectional view showing a manufacturing step of the light emitting device according to a second embodiment.

FIG. 28 is a perspective view showing a light emitting device according to a third embodiment.

FIG. 29 is a cross-sectional view illustrating a light emitting device according to the third embodiment.

FIG. 30 is a perspective view showing a light emitting device according to a fourth embodiment.

FIG. 31 is a cross-sectional view illustrating a light emitting device according to the fourth embodiment.

FIG. 32 is a perspective view showing a light emitting device according to a fifth embodiment.

FIG. 33 is a perspective view showing the backlight unit of the embodiment. FIG. 34 is a perspective view showing the illumination device of the embodiment.

### MODE FOR INVENTION

In the description of the embodiments, it is to be understood if each layer (film), region, pattern or structure may be referred to as being “on/over” or “under” the substrate, each layer, region, pad or patterns, it is to be understood that the terms “on/over” and “ under ” comprise both “ directly ” or “ indirectly”. In addition, standards for top, bottom, or bottom of each layer will be described with reference to the drawings.

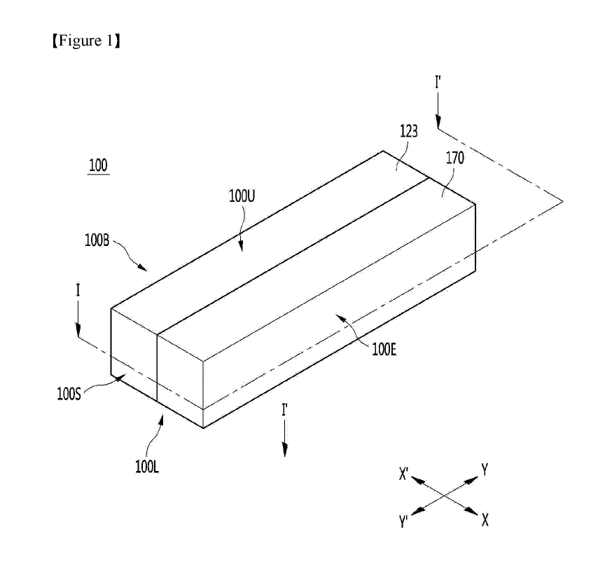

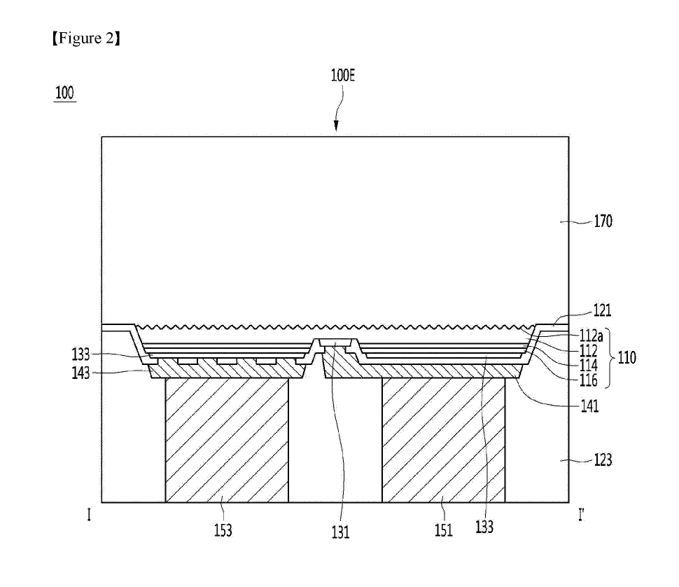

FIG. 1 is a perspective view illustrating a light emitting device according to a first embodiment, and FIG. 2 is a cross-sectional view illustrating a light emitting device cut along a line I-I′ of FIG. 1, and FIG. 3 is a bottom view of the device according to the first embodiment.

As shown in FIGS. 1 to 3, the light emitting device 100 of the first embodiment may be a side view type. The light emitting device 100 may comprise an emission unit 100E through which light is emitted to one side. The light emitting device 100 may comprise a rear surface 100B that is symmetrical with the emitting unit 100E in the first direction X-X′ direction. The light emitting device 100 may comprise an upper portion 100U and a lower portion 100L arranged in a second direction Y-Y′ orthogonal to the first direction X-X′. The upper portion 100U and the lower portion 100L may be symmetrical to each other. Here, the second direction Y-Y′ may be defined as the major axis direction of the light emitting device 100. The light emitting device 100 may comprise side portions 100S that are symmetrical with respect to each other, which are disposed in a direction perpendicular to the upper portion 100U and the lower portion 100L.

In the light emitting device 100, the phosphor layer 170 may be disposed in the emitting portion 100E. The phosphor layer 170 may comprise a fluorescent material that converts light into light having a white wavelength. For example, the phosphor layer 170 may comprise, but is not limited to, a yellow fluorescent material that converts light having a blue wavelength to a white wavelength.

The light emitting device 100 may comprise first and second pads 151 and 153 on the lower portion 100L. The light emitting device 100 of the first embodiment may have a light emitting portion 100E disposed on one side and a first and a second pads 151 and 153 disposed on the lower portion 100L to implement thinness and slimness.

Specifically, the light emitting device 100 comprises a light emitting structure 110, a first insulating layer 121, a second insulating layer 123, a first electrode 131, a second electrode 133, 141, a second connection electrode 143, and first and second pads 151, 153.

The light emitting structure 110 may be in direct contact with the phosphor layer 170. The light emitting structure 110 may comprise a first conductivity type semiconductor layer 112, an active layer 114, and a second conductivity type semiconductor layer 116.

The first conductivity type semiconductor layer 112 may be formed of a semiconductor compound, for example, a compound semiconductor such as Group II-IV or Group III-V. The first conductivity type semiconductor layer 112 may be a single layer or a multilayer. The first conductivity type semiconductor layer 112 may be doped with a first conductive dopant. For example, when the first conductivity type semiconductor layer 112 is an n-type semiconductor layer, it may comprise an n-type dopant. For example, the n-type dopant may comprise but is not limited to Si, Ge, Sn, Se, and Te. The first conductivity type semiconductor layer 112 may comprise a semiconductor material having a composition formula of InₓAl_{y}Ga_{1-x-y}N(0≤x≤1, 0≤y≤1, 0≤x+y≤1), but is not limited thereto. For example, the first conductivity type semiconductor layer 112 may be selected from GaN, AlN, AlGaN, InGaN, InN, InAlGaN, AlInN, AlGaAs, GaP, GaAs, GaAsP, AlGaInP and the like.

The first conductivity type semiconductor layer 112 may comprise a light extracting structure 112a. The light extracting structure 112a may be a shape having a section and an inclination, but is not limited thereto and may be a shape having a polygon or a curvature. The light extracting structure 112a can improve light extraction efficiency.

The active layer 114 may be disposed on the first conductivity type semiconductor layer 112. The active layer 114 may optionally comprise a single quantum well, a multiple quantum well (MQW), a quantum wire structure, or a quantum dot structure. The active layer 114 may be formed of a compound semiconductor. The active layer 114 may be formed of at least one of Group II-IV and Group III-V compound semiconductors.

When the active layer 114 is implemented as a multiple quantum well structure (MQW), quantum wells and quantum wells may be alternately arranged. The quantum well and the quantum well may be a semiconductor material having a composition formula of InₓAl_{y}Ga_{1-x-y}N(0≤x≤1, 0≤y≤1, 0≤x+y≤1). For example, the active layer 114 may comprise one or more of InGaN/GaN, InGaN/AlGaN, InGaN/InGaN, InAlGaN/InAlGaN, GaN/AlGaN, InAlGaN/GaN, GaInP/AlGaInP, GaP/AlGaP, InGaP/AlGaP, GaAs/AlGaAs, InGaAs/AlGaAs, but is not limited thereto.

The second conductivity type semiconductor layer 116 may be disposed under the active layer 114. The second conductivity type semiconductor layer 116 may be formed of a semiconductor compound such as a Group II-IV and a Group III-V compound semiconductor. The second conductivity type semiconductor layer 116 may be a single layer or a multilayer. The second conductivity type semiconductor layer 116 may be doped with a second conductive dopant. For example, when the second conductivity type semiconductor layer 116 is a p-type semiconductor layer, it may comprise a p-type dopant. For example, the p-type dopant may comprise Mg, Zn, Ca, Sr, Ba, and the like, but is not limited thereto. The second conductivity type semiconductor layer 116 may comprise a semiconductor material having a composition formula of InₓAl_{y}Ga_{1-x-y}N(0≤x<1, 0≤y≤1, 0≤x+y≤1), but is not limited thereto. For example, the second conductivity type semiconductor layer 116 may be selected from GaN, AlN, AlGaN, InGaN, InN, InAlGaN, AlInN, AlGaAs, GaP, GaAs, GaAsP, AlGaInP and the like.

Although the light emitting structure 112 is described as defining the first conductivity type semiconductor layer 112 of the n-type semiconductor layer and the second conductivity type semiconductor layer 116 of the p-type semiconductor layer, The layer 112 may be formed as a p-type semiconductor layer, and the second conductivity type semiconductor layer 116 may be formed as an n-type semiconductor layer, but the present invention is not limited thereto. An n-type semiconductor layer (not shown) may be formed on the second conductivity type semiconductor layer 116, for example, to have a polarity opposite to that of the second conductive type. Accordingly, the light emitting structure 110 may have any one of an n-p junction structure, a p-n junction structure, an n-p-n junction structure, and a p-n-p junction structure.

The first electrode 131 may be electrically connected to the first conductivity type semiconductor layer 112. The first electrode 131 may be disposed on the first conductivity type semiconductor layer 112. The first electrode 131 may be disposed on the first conductivity type semiconductor layer 112 exposed by mesa etching the active layer 114 and the second conductivity type semiconductor layer 116. Here, the light extracting structure 112a may be disposed on one surface of the first conductivity type semiconductor layer 112, and the first electrode 131 may be disposed on the other surface of the first conductivity type semiconductor layer 112. The first electrode 131 of the first embodiment may be disposed in an intermediate region of the light emitting structure 110, but the present invention is not limited thereto.

The second electrode 133 may be electrically connected to the second conductive type semiconductor layer 116. The second electrode 133 may be disposed on the second conductivity type semiconductor layer 116. The second electrode 133 may be in direct contact with the second conductivity type semiconductor layer 116. The second electrode 133 may be spaced apart from the first electrode 131 by a predetermined distance.

The first and second electrodes 131 and 133 may comprise a function of reflecting light emitted from the light emitting structure 110. The first and second electrodes 131 and 133 may reflect light from the light emitting structure 110 to the outside to improve light extraction efficiency. The first and second electrodes 131 and 133 may comprise a metal material. For example, the first and second electrodes 131 and 133 may be formed of a metal or an alloy including at least one of Ag, Ni, Al, Rh, Pd, Ir, Ru, Mg, Zn, Pt, Cu, Au, and Hf, and Ti. The first and second electrodes 131 and 133 are formed of a metal or an alloy of ITO(Indium-Tin-Oxide), IZO(Indium-Zinc-Oxide), IZTO(Indium-Zinc-Tin-Oxide), IAZO(Indium-Aluminum-Zinc-Oxide), IGZO(Indium-Gallium-Zinc-Oxide), IGTO(Indium-Gallium-Tin-Oxide), AZO(Aluminum-Zinc-Oxide), ATO(Antimony-Tin-Oxide) and the like, and may be a single layer or multiple layers of conductive material.

The first insulating layer 121 may be disposed on the light emitting structure 110 and the first and second electrodes 131 and 133. The first insulating layer 121 may extend outside the light emitting structure 110. For example, a portion of the first insulating layer 121 may be disposed in parallel to the light extracting structure 112a of the first conductivity type semiconductor layer 112. A part of the first insulating layer 121 may directly contact the phosphor layer 170. The first insulating layer 121 may comprise a via hole exposing the first and second electrodes 131 and 133. The first insulating layer 121 may be an oxide or a nitride. For example, the first insulating layer 121 may be at least one selected from the group consisting of SiO₂, SiₓO_{y}, Si₃N₄, SiₓN_{y}, SiOₓN_{y}, Al₂O₃, TiO₂, AlN and the like.

The first and second connection electrodes 141 and 143 may be disposed on the first insulation layer 121.

The first connection electrode 141 may be electrically connected to the first electrode 131 exposed from the first insulation layer 121. The first connection electrode 141 may be in direct contact with the first electrode 131. The first connection electrode 141 may be disposed on the first electrode 131 and extend on the first insulation layer 121.

The second connection electrode 143 may be electrically connected to the second electrode 133 exposed from the first insulation layer 121. The second connection electrode 143 may be in direct contact with the second electrode 133. The second connection electrode 143 may be disposed on the second electrode 133 and extend on the first insulation layer 121.

The first and second connection electrodes 141 and 143 may be a metal or an alloy including at least one of Ag, Ni, Al, Rh, Pd, Ir, Ru, Mg, Zn, Pt, Cu, Au and Hf The first and second connection electrodes 141 and 143 are formed of a metal or an alloy of ITO(Indium-Tin-Oxide), IZO(Indium-Zinc-Oxide), IZTO(Indium-Zinc-Tin-Oxide), IAZO(Indium-Aluminum-Zinc-Oxide), IGZO(Indium-Gallium-Zinc-Oxide), IGTO(Indium-Gallium-Tin-Oxide), AZO(Aluminum-Zinc-Oxide), ATO(Antimony-Tin-Oxide) and may be a single layer or multiple layers of a transparent conductive material.

The first pad 151 may be electrically connected to the first connection electrode 141. The first pad 151 may be in direct contact with the first connection electrode 141. The first pad 151 may be disposed on the first connection electrode 141 and the end of the first pad 151 may be exposed to the lower portion 100L of the light emitting device 100.

The second pad 153 may be electrically connected to the second connection electrode 143. The second pad 153 may be in direct contact with the second connection electrode 143. The second pad 153 may be disposed on the second connection electrode 143 and the end of the second pad 153 may be exposed to the lower portion 100L of the light emitting device 100.

The first and second pads 151 and 153 may be a metal or an alloy including at least one of Ag, Ni, Al, Rh, Pd, Ir, Ru, Mg, Zn, Pt, Cu, Au, and Hf The first and second pads 151 and 153 are formed of a metal or an alloy of ITO(Indium-Tin-Oxide), IZO(Indium-Zinc-Oxide), IZTO(Indium-Zinc-Tin-Oxide), IAZO(Indium-Aluminum-Zinc-Oxide), IGZO(Indium-Gallium-Zinc-Oxide), IGTO(Indium-Gallium-Tin-Oxide), AZO(Aluminum-Zinc-Oxide), ATO(Antimony-Tin-Oxide) and may be a single layer or multiple layers of conductive material.

The second insulating layer 123 may be disposed on the first insulating layer 121, the first and second connecting electrodes 141 and 143, and the first and second pads 151 and 153. The second insulation layer 123 may be formed by adding a heat spreader to a resin such as silicon or epoxy. The heat spreader may comprise at least one material selected from the group consisting of oxides, nitrides, fluorides, and sulfides having a material such as Al, Cr, Si, Ti, Zn, and Zr. The heat spreader may be defined as a powder particle, a grain, a filler, or an additive having a predetermined size.

The light emitting device 100 of the first embodiment comprises the first and second pads 151 and 153 exposed at the bottom and the light emitting unit 100E at one side and the phosphor layer 170 is formed in the light emitting unit 100E. So that a side view type light emitting device having a simplified structure can be implemented.

The light emitting device 100 of the first embodiment can be made thinner and slimmer than a general light emitting device package having a connection structure of a light emitting chip and a lead frame by a simplified structure.

The light emitting device 100 of the first embodiment can improve the light efficiency by resolving the light loss by the simplified structure.

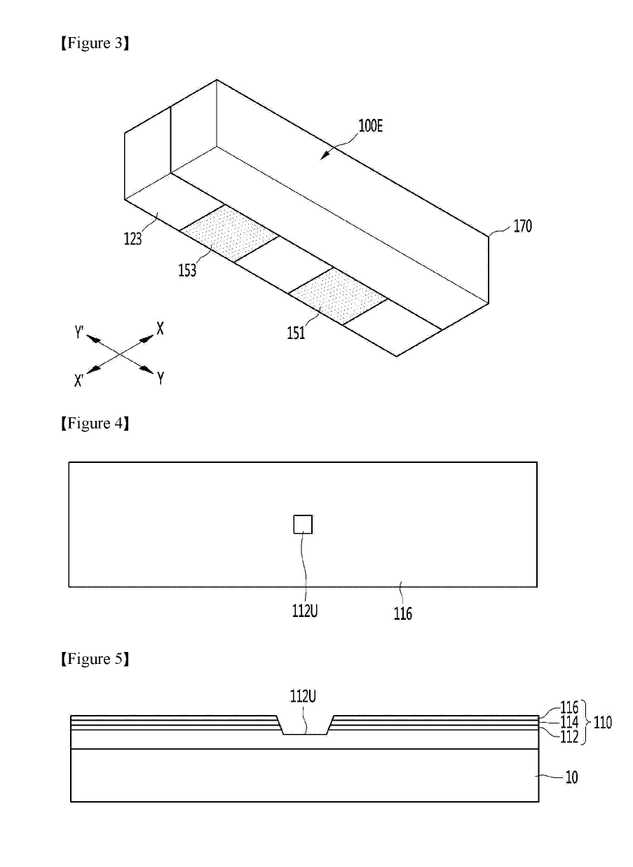

FIGS. 4 to 15 are a plan view and a cross-sectional view illustrating a manufacturing step of the light emitting device according to the first embodiment.

Referring to FIGS. 4 and 5, the light emitting device according to the first embodiment comprises a light emitting structure 110 formed on a substrate 10, a first conductivity type semiconductor layer 112 may be exposed from the active layer 114 and the second conductivity type semiconductor layer 116. In this case,

The substrate 10 may be formed as a single layer or multiple layers. The substrate 10 may be a conductive substrate or an insulating substrate. For example, the substrate 10 may be at least one of GaAs, sapphire (Al₂O₃), SiC, Si, GaN, ZnO, GaP, InP, Ge and Ga₂O₃. The substrate 10 may be cleaned before forming the light emitting structure 110 to remove impurities on the surface.

For example, the light emitting structure 110 may be formed by a metal organic chemical vapor deposition (MOCVD) method, a chemical vapor deposition (CVD) method, a plasma enhanced chemical vapor deposition (PECVD) method, Molecular beam epitaxy (MBE), and Hydride vapor phase epitaxy (HVPE), and the like, but the present invention is not limited thereto. The first conductivity type semiconductor layer 112, the active layer 114, and the second conductivity type semiconductor layer 116 may adopt the technical features of the light emitting device 100 of the first embodiment shown in FIGS. 1 to 3.

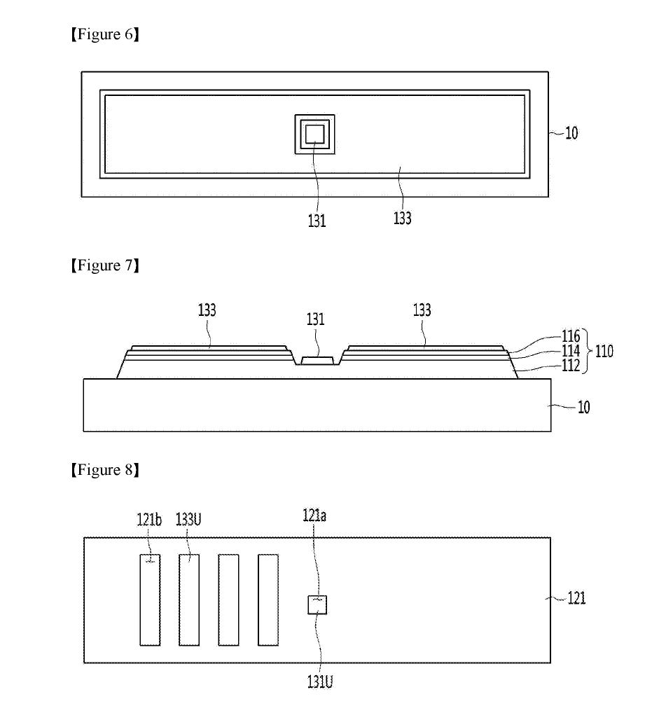

Referring to FIGS. 6 and 7, the first and second electrodes 131 and 133 may be formed on the light emitting structure 110. The first electrode 131 may be disposed on the first conductivity type semiconductor layer 112 and the second electrode 133 may be disposed on the second conductivity type semiconductor layer 116. The light emitting structure 110 may be selectively etched through the isolation etching to expose the edge of the substrate 10. The isolation etching may be performed by, for example, dry etching such as ICP (Inductively Coupled Plasma), but is not limited thereto.

The first and second electrodes 131 and 133 may comprise a metal material. For example, the first and second electrodes 131 and 133 may be a metal or an alloy including at least one of Ag, Ni, Al, Rh, Pd, Ir, Ru, Mg, Zn, Pt, Cu, Au, and H. The first and second electrodes 131 and 133 are formed of a metal or an alloy of ITO(Indium-Tin-Oxide), IZO(Indium-Zinc-Oxide), IZTO(Indium-Zinc-Tin-Oxide), IAZO(Indium-Aluminum-Zinc-Oxide), IGZO(Indium-Gallium-Zinc-Oxide), IGTO(Indium-Gallium-Tin-Oxide), AZO(Aluminum-Zinc-Oxide), ATO(Antimony-Tin-Oxide) and may be a single layer or multiple layers of conductive material.

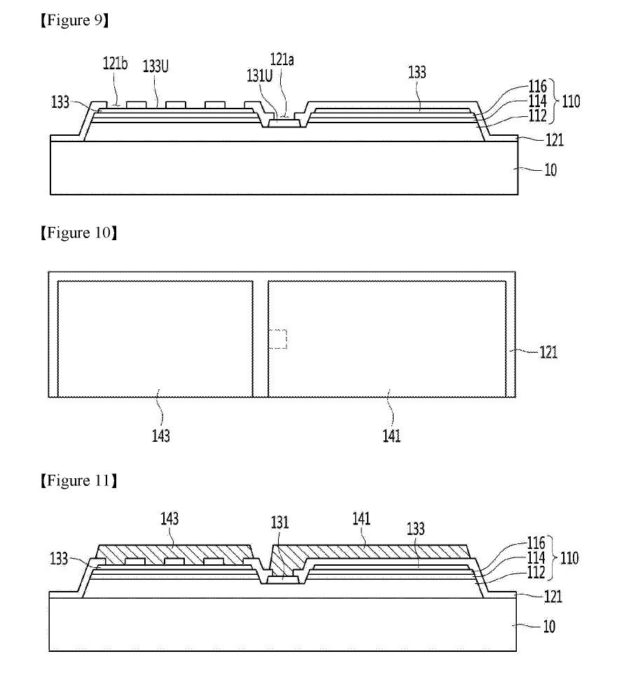

Referring to FIGS. 8 and 9, a first insulating layer 121 may be formed on the light emitting structure 110, the first and second electrodes 131 and 133. The first insulating layer 121 may extend over the substrate 10 exposed outside the light emitting structure 110. The first insulating layer 121 may comprise a first via hole 121a exposing a portion 131U of the first electrode 131 and a plurality of second via holes 121a exposing a portion 133U of the second electrode 133. The first insulating layer 121 may be an oxide or a nitride. For example, the first insulating layer 121 may be at least one selected from the group consisting of SiO₂, SiₓO_{y}, Si₃N₄, SiₓN_{y}, SiOₓN_{y}, Al₂O₃, TiO₂, AlN and the like.

Referring to FIGS. 10 and 11, the first and second connection electrodes 141 and 143 may be formed on the first insulating layer 121. The first connection electrode 141 may be electrically connected to the first electrode 131 and the second connection electrode 143 may be electrically connected to the second electrode 133.

The first and second connection electrodes 141 and 143 may be a metal or an alloy including at least one of Ag, Ni, Al, Rh, Pd, Ir, Ru, Mg, Zn, Pt, Cu, Au, and Hf The first and second connection electrodes 141 and 143 are formed of a metal or an alloy of ITO(Indium-Tin-Oxide), IZO(Indium-Zinc-Oxide), IZTO(Indium-Zinc-Tin-Oxide), IAZO(Indium-Aluminum-Zinc-Oxide), IGZO(Indium-Gallium-Zinc-Oxide), IGTO(Indium-Gallium-Tin-Oxide), AZO(Aluminum-Zinc-Oxide), ATO(Antimony-Tin-Oxide) and may be a single layer or multiple layers of a transparent conductive material.

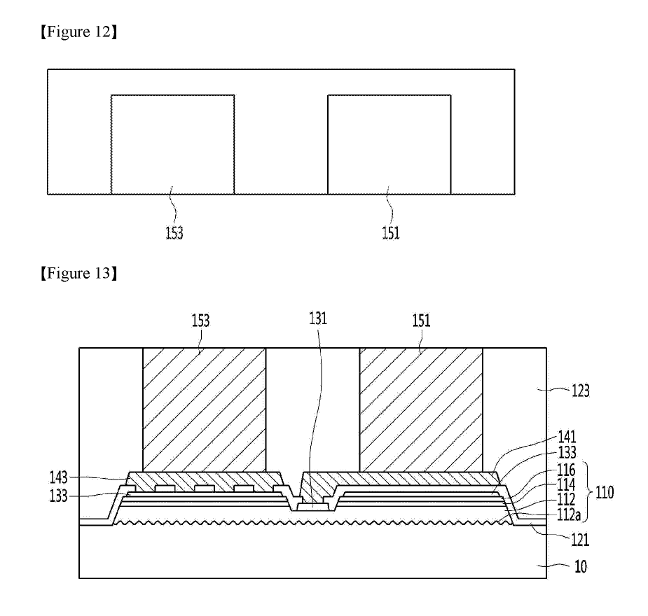

Referring to FIGS. 12 and 13, the first and second pads 151 and 153 may be formed on the first and second connection electrodes 141 and 143, respectively. The second insulating layer 123 may be formed on the first insulating layer 121, the first and second connecting electrodes 141 and 143, and the first and second pads 151 and 153.

The first and second pads 151 and 153 may be a metal or an alloy including at least one of Ag, Ni, Al, Rh, Pd, Ir, Ru, Mg, Zn, Pt, Cu, Au, and Hf The first and second pads 151 and 153 are formed of a metal or an alloy of ITO(Indium-Tin-Oxide), IZO(Indium-Zinc-Oxide), IZTO(Indium-Zinc-Tin-Oxide), IAZO(Indium-Aluminum-Zinc-Oxide), IGZO(Indium-Gallium-Zinc-Oxide), IGTO(Indium-Gallium-Tin-Oxide), AZO(Aluminum-Zinc-Oxide), ATO(Antimony-Tin-Oxide) and may be a single layer or multiple layers of conductive material.

The second insulation layer 123 may be formed by adding a heat spreader to a resin such as silicon or epoxy. The heat spreader may comprise at least one material selected from the group consisting of oxides, nitrides, fluorides, and sulfides having a material such as Al, Cr, Si, Ti, Zn, and Zr. The heat spreader may be defined as a powder particle, a grain, a filler, or an additive having a predetermined size.

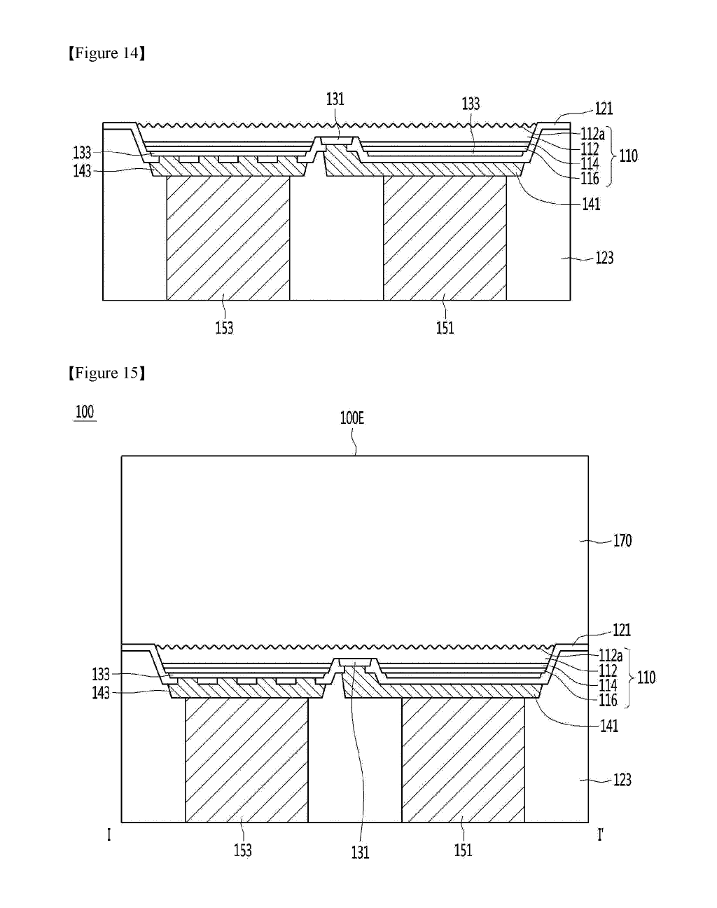

Referring to FIG. 14, the substrate (10 in FIG. 13) may be removed from the light emitting structure 110. For example, the substrate (10 of FIG. 13) may be removed by a laser lift off (LLO) process, but is not limited thereto. Here, the laser lift-off process (LLO) is a process of irradiating a laser beam to the lower surface of the substrate (10 of FIG. 13) to peel off the substrate (10 of FIG. 13) and the light emitting structure 110 from each other.

The upper surface of the first conductivity type semiconductor layer 112 may have a light extracting structure 112a. For example, the light extracting structure 112a may be formed by a PEC (Photo Electro Chemical) etching process, but is not limited thereto. The light extracting structure 112a may comprise a function for extracting light in the light emitting structure 110 to the outside, thereby increasing the light extracting effect.

Referring to FIG. 15, a phosphor layer 170 may be formed on the light emitting structure 110. The phosphor layer 170 may comprise a fluorescent material that converts light into light having a white wavelength. For example, the phosphor layer 170 may comprise, but is not limited to, a yellow fluorescent material that converts light having a blue wavelength to a white wavelength.

The light emitting device 100 of the first embodiment can reduce the manufacturing process and improve the productivity compared with a general light emitting device package having a connection structure of the light emitting chip and the lead frame by the simplified structure.

The light emitting device 100 of the first embodiment comprises the first and second pads 151 and 153 exposed at the bottom and the light emitting unit 100E at one side and the phosphor layer 170 is formed in the light emitting unit 100E. So that a side view type light emitting device having a simplified structure can be implemented.

The light emitting device 100 of the first embodiment can be made thinner and slimmer than a general light emitting device package having a connection structure of a light emitting chip and a lead frame by a simplified structure.

The light emitting device 100 of the first embodiment can improve the light efficiency by resolving the light loss by the simplified structure.

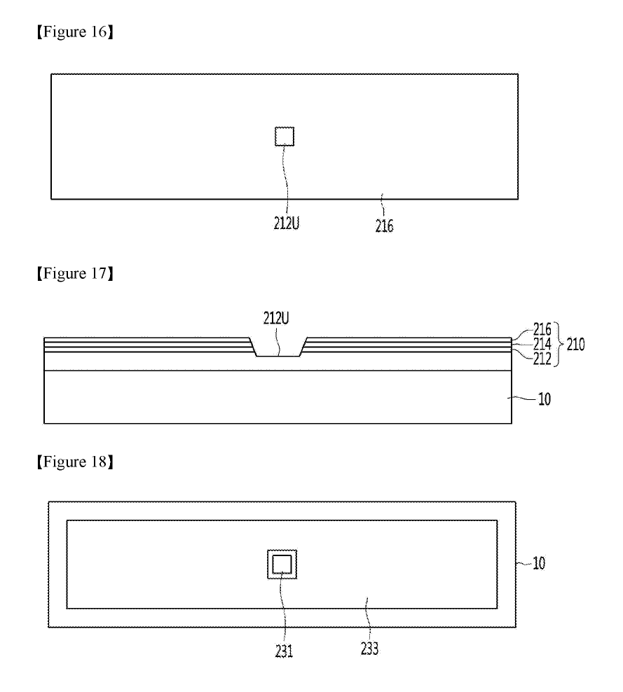

FIGS. 16 to 27 are a plan view and a cross-sectional view showing a manufacturing step of the light emitting device according to the second embodiment.

Referring to the FIGS. 16 and 17, the manufacturing process of the light emitting device according to the second embodiment comprises forming a light emitting structure 210 on a substrate 10, forming a first conductivity type semiconductor layer 212 May be exposed from the active layer 214 and the second conductivity type semiconductor layer 216.

The substrate 10 may be formed as a single layer or multiple layers. The substrate 10 may be a conductive substrate or an insulating substrate. For example, the substrate 10 may be at least one of GaAs, sapphire (Al₂O₃), SiC, Si, GaN, ZnO, GaP, InP, Ge and Ga₂O₃. The substrate 10 may be cleaned before the light emitting structure 210 is formed to remove impurities on the surface.

For example, the light emitting structure 210 may be formed using a metal organic chemical vapor deposition (MOCVD) method, a chemical vapor deposition (CVD) method, a plasma enhanced chemical vapor deposition (PECVD) method, Molecular beam epitaxy (MBE), and Hydride vapor phase epitaxy (HVPE), and the like, but the present invention is not limited thereto. The first conductivity type semiconductor layer 212, the active layer 214, and the second conductivity type semiconductor layer 216 may adopt the technical features of the light emitting device 100 of the first embodiment shown in FIGS. 1 to 3.

Referring to FIGS. 18 and 19, the first and second electrodes 231 and 233 may be formed on the light emitting structure 210. The first electrode 231 may be disposed on the first conductivity type semiconductor layer 212 and the second electrode 233 may be disposed on the second conductivity type semiconductor layer 216.

The first and second electrodes 231 and 233 may comprise a metal material. For example, the first and second electrodes 231 and 233 may be a metal or an alloy including at least one of Ag, Ni, Al, Rh, Pd, Ir, Ru, Mg, Zn, Pt, Cu, Au, and Hf The first and second electrodes 231 and 233 are formed of a metal or an alloy of ITO(Indium-Tin-Oxide), IZO(Indium-Zinc-Oxide), IZTO(Indium-Zinc-Tin-Oxide), IAZO(Indium-Aluminum-Zinc-Oxide), IGZO(Indium-Gallium-Zinc-Oxide), IGTO(Indium-Gallium-Tin-Oxide), AZO(Aluminum-Zinc-Oxide), ATO(Antimony-Tin-Oxide) and may be a single layer or multiple layers of conductive material.

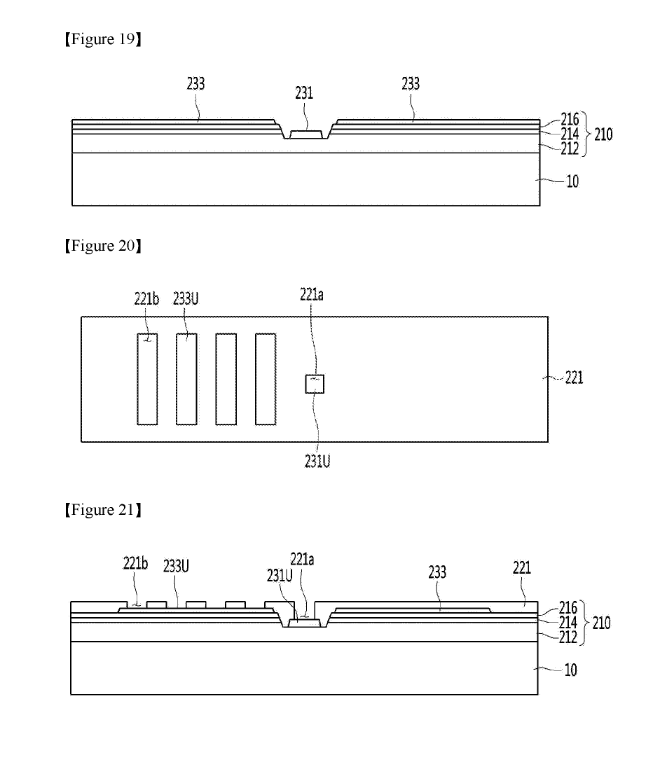

Referring to FIGS. 20 and 21, a first insulating layer 221 may be formed on the light emitting structure 210, the first and second electrodes 231 and 233. The first insulating layer 221 comprises a first via hole 221a exposing a portion 231U of the first electrode 231 and a plurality of second via holes 221a exposing a portion 233U of the second electrode 233. 2 via-hole 221b. The first insulating layer 221 may be an oxide or a nitride. For example, the first insulating layer 221 may be at least one selected from the group consisting of SiO₂, SiₓO_{y}, Si₃N₄ Si_{X}N_{y} SiOₓN_{y}, Al₂O₃, TiO₂, and AlN.

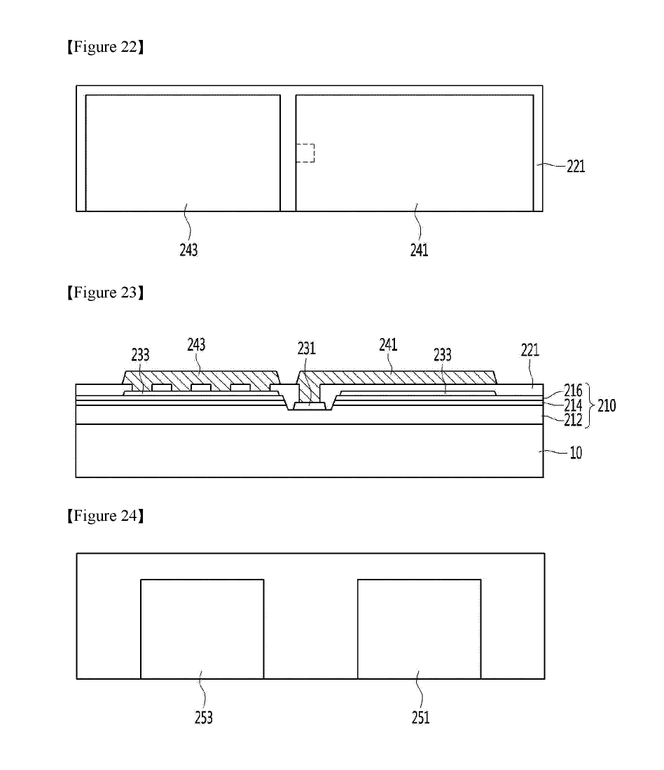

Referring to FIGS. 22 and 23, the first and second connection electrodes 241 and 243 may be formed on the first insulating layer 221. The first connection electrode 241 may be electrically connected to the first electrode 231 and the second connection electrode 243 may be electrically connected to the second electrode 233.

The first and second connection electrodes 241 and 243 may be a metal or an alloy including at least one of Ag, Ni, Al, Rh, Pd, Ir, Ru, Mg, Zn, Pt, Cu, Au, and Hf The first and second connection electrodes 241 and 243 may be formed of a metal or an alloy of ITO(Indium-Tin-Oxide), IZO(Indium-Zinc-Oxide), IZTO(Indium-Zinc-Tin-Oxide), IAZO(Indium-Aluminum-Zinc-Oxide), IGZO(Indium-Gallium-Zinc-Oxide), IGTO(Indium-Gallium-Tin-Oxide), AZO(Aluminum-Zinc-Oxide), ATO(Antimony-Tin-Oxide) and may be a single layer or multiple layers of a transparent conductive material.

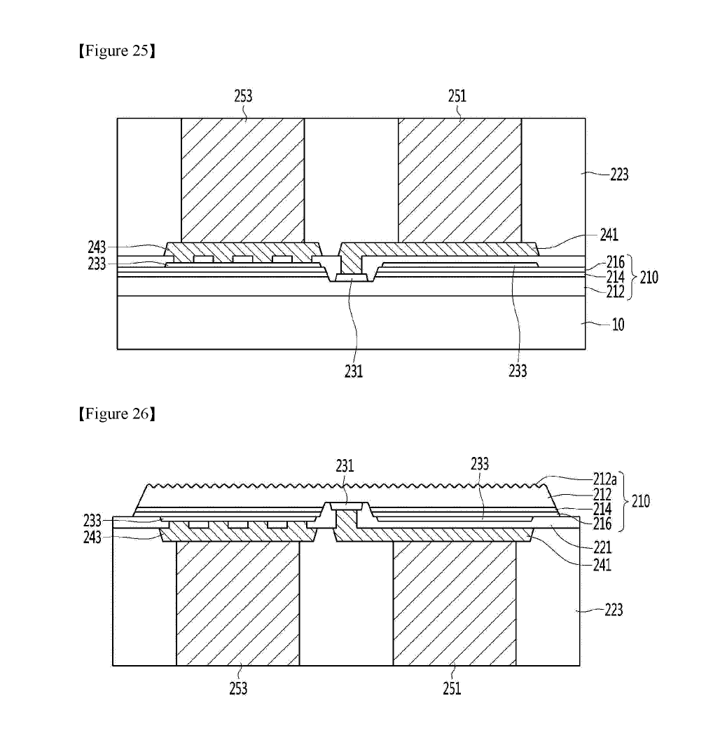

Referring to FIGS. 24 and 25, the first and second pads 251 and 253 may be formed on the first and second connection electrodes 241 and 243, respectively. The second insulating layer 223 may be formed on the first insulating layer 221, the first and second connecting electrodes 241 and 243, and the first and second pads 251 and 253.

The first and second pads 251 and 253 may be a metal or an alloy including at least one of Ag, Ni, Al, Rh, Pd, Ir, Ru, Mg, Zn, Pt, Cu, Au, and Hf. The first and second pads 151 and 153 are formed of a metal or an alloy of ITO(Indium-Tin-Oxide), IZO(Indium-Zinc-Oxide), IZTO(Indium-Zinc-Tin-Oxide), IAZO(Indium-Aluminum-Zinc-Oxide), IGZO(Indium-Gallium-Zinc-Oxide), IGTO(Indium-Gallium-Tin-Oxide), AZO(Aluminum-Zinc-Oxide), ATO(Antimony-Tin-Oxide) and may be a single layer or multiple layers of conductive material.

The second insulation layer 223 may be formed by adding a heat spreader to a resin such as silicon or epoxy. The heat spreader may comprise at least one material selected from the group consisting of oxides, nitrides, fluorides, and sulfides having a material such as Al, Cr, Si, Ti, Zn, and Zr. The heat spreader may be defined as a powder particle, a grain, a filler, or an additive having a predetermined size.

Referring to FIG. 26, the substrate (10 in FIG. 25) may be removed from the light emitting structure 210. For example, the substrate (10 of FIG. 25) may be removed by a laser lift off (LLO) process, but is not limited thereto. The laser lift-off process (LLO) is a process of irradiating a laser beam to the lower surface of the substrate (10 of FIG. 25) to peel the substrate (10 of FIG. 25) and the light emitting structure 210 from each other.

The exposed portion of the first conductivity type semiconductor layer 212 may be selectively etched through isolation etching to expose the edge of the first insulating layer 221. The isolation etching may be performed by, for example, dry etching such as ICP (Inductively Coupled Plasma), but is not limited thereto.

The upper surface of the first conductive type semiconductor layer 212 exposed from the substrate (10 of FIG. 25) may be formed with a light extracting structure 212a. For example, the light extracting structure 212a may be formed by a PEC (Photo Electro Chemical) etching process, but the present invention is not limited thereto. The light extracting structure 212a may comprise a function of extracting the light in the light emitting structure 210 to the outside, thereby enhancing the light extracting effect.

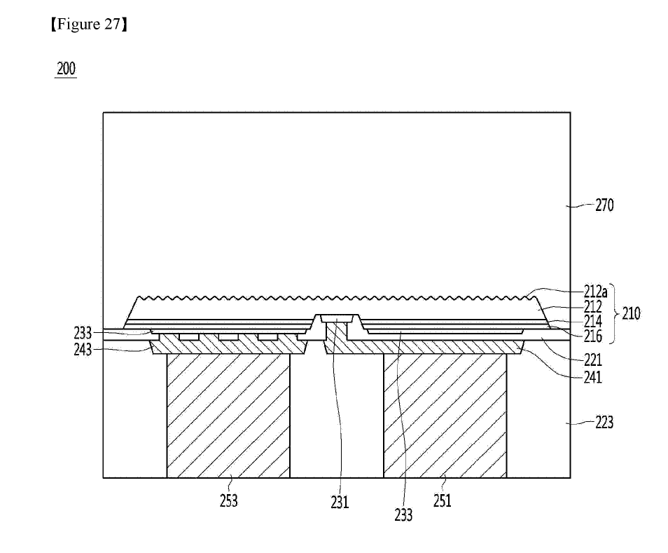

Referring to FIG. 27, a phosphor layer 270 may be formed on the light emitting structure 210 and the first insulating layer 221. The phosphor layer 270 may comprise a fluorescent material that converts light into light having a white wavelength. For example, the phosphor layer 270 may comprise, but is not limited to, a yellow fluorescent material that converts light having a blue wavelength to a white wavelength.

The light emitting device 200 of the second embodiment can reduce the manufacturing process and improve the productivity compared with a general light emitting device package having a connection structure of the light emitting chip and the lead frame by the simplified structure.

The light emitting device 200 of the second embodiment has a structure in which the first and second pads 251 and 253 are exposed at a lower portion and the light emitting portion is disposed at one side and the phosphor layer 270 is disposed at the light emitting portion, A side view type light emitting device can be implemented.

The light emitting device 200 of the second embodiment can be made thinner and slimmer than a general light emitting device package having a connection structure of a light emitting chip and a lead frame by a simplified structure.

The light emitting device 200 of the second embodiment can improve the light efficiency by resolving the light loss by the simplified structure.

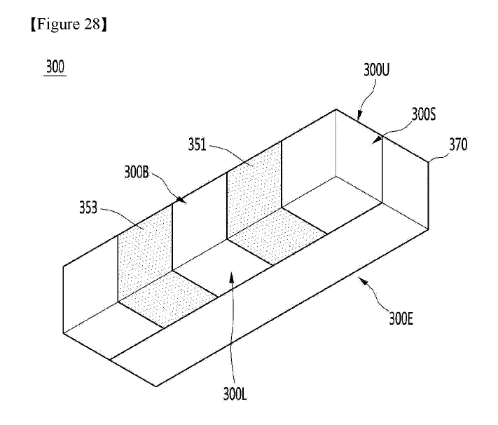

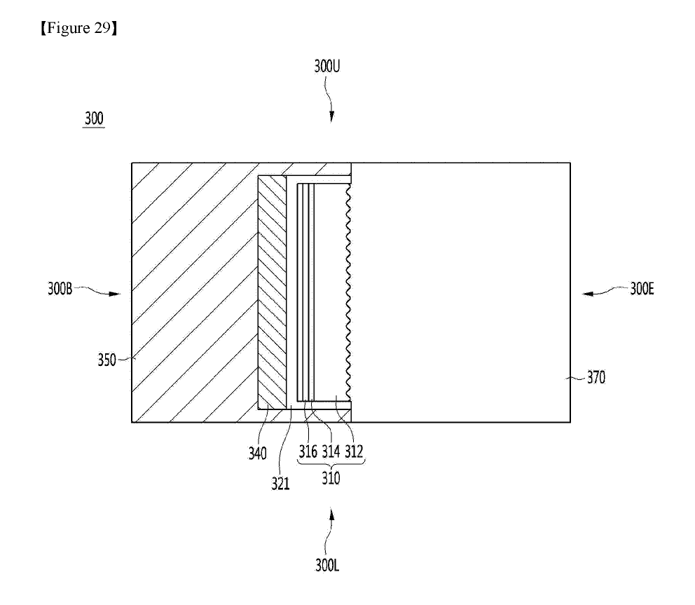

FIG. 28 is a perspective view illustrating a light emitting device according to a third embodiment, and FIG. 29 is a cross-sectional view illustrating a light emitting device according to the third embodiment.

As shown in FIGS. 28 and 29, the light emitting device 300 according to the third embodiment may comprise first and second pads 351 and 353. The light emitting device 300 comprises an emission part 300E on one side and a phosphor layer 370 on the emission part 300E. The light emitting device 300 comprises a light emitting structure 310 including a first conductivity type semiconductor layer 312, an active layer 314 and a second conductivity type semiconductor layer 316 and a light emitting structure 310 including an electrode 321, And first and second pads 351 and 353. Structures other than the first and second pads 351 and 353 may adopt the technical features of the light emitting device 100 of the first embodiment of FISGS. 1 to 3.

The first and second pads 351 and 353 may be exposed to the rear surface 300B, the upper portion 300U and the lower portion 300L of the light emitting device 300. The light emitting device 300 according to the third embodiment may have the first and second pads 351 and 353 exposed symmetrically to the rear face 300B, the upper face 300U and the lower face 300L, The bonding force between the two pads 351 and 353 and the insulating layer can be improved.

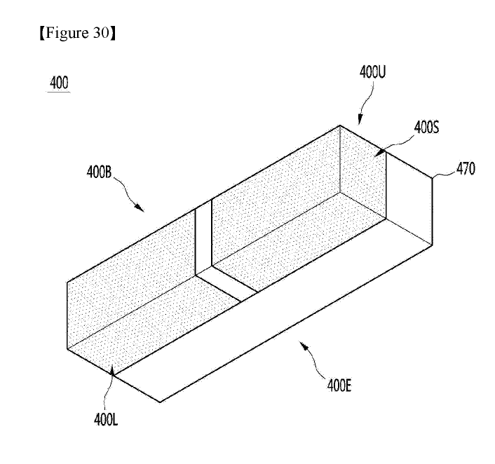

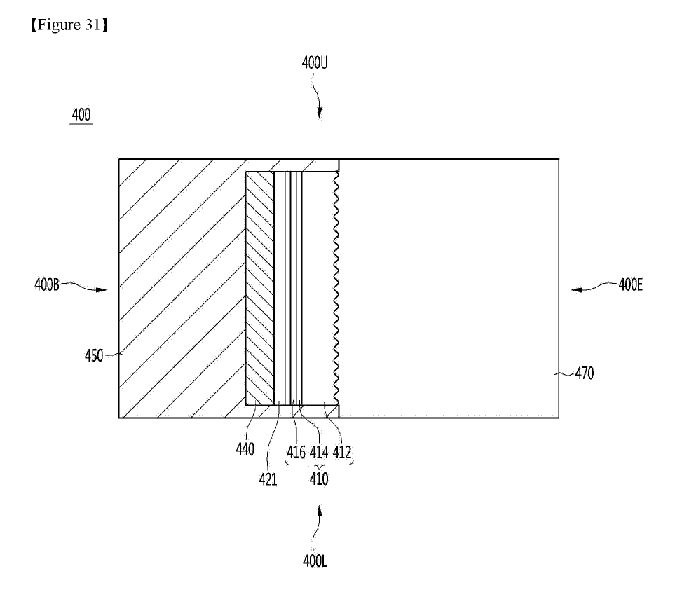

FIG. 30 is a perspective view illustrating a light emitting device according to a fourth embodiment, and FIG. 31 is a cross-sectional view illustrating a light emitting device according to the fourth embodiment.

As shown in FIGS. 30 and 31, the light emitting device 400 according to the fourth embodiment may comprise first and second pads 451 and 453. The light emitting device 400 comprises an emission portion 400E on one side and the phosphor layer 470 on the emission portion 400E. The light emitting device 400 comprises a light emitting structure 410 including a first conductivity type semiconductor layer 412, an active layer 414 and a second conductivity type semiconductor layer 416, an electrode 421, a connection electrode 440 And first and second pads 451 and 453. Structures other than the first and second pads 451 and 453 may adopt the technical features of the light emitting device 100 of the first embodiment of FIGS. 1 to 3.

The first and second pads 451 and 453 may be exposed to the rear surface 400B, the upper portion 400U, the lower portion 400L, and the side portion 400S of the light emitting device 400. The light emitting device 400 according to the fourth embodiment is formed by the structure of the first and second pads 451 and 453 exposed symmetrically to the rear face 400B, the upper face 400U, the lower face 400L and the side face 400S The bonding force between the first and second pads 451 and 453 and the insulating layer can be improved.

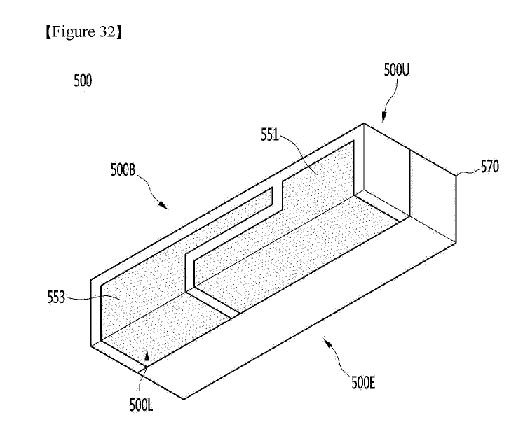

FIG. 32 is a perspective view showing a light emitting device according to a fifth embodiment.

As shown in FIG. 32, the light emitting device 500 according to the fifth embodiment may comprise first and second pads 551 and 553. The light emitting device 500 comprises an emission portion 500E on one side and a phosphor layer 570 on the emission portion 500E. Structures other than the first and second pads 551 and 553 may adopt the technical features of the light emitting device 100 of the first embodiment of FIGS. 1 to 3.

The first and second pads 551 and 553 may be exposed to the rear surface 500B of the light emitting device 500. The first and second pads 551 and 553 exposed to the rear surface 500B of the light emitting device 500 may have a structure symmetrical to each other in a diagonal direction. For example, a part of the first and second pads 551 and 553 may be vertically overlapped on the rear surface 500B of the light emitting device 500.

The light emitting device 500 according to the fifth embodiment may comprise the first and second pads 551 and 553 by the first and second pads 551 and 553 that are symmetrically exposed in the diagonal direction on the rear surface 500B, And the strength between the first and second pads 551 and 553 in the vertical direction can be improved.

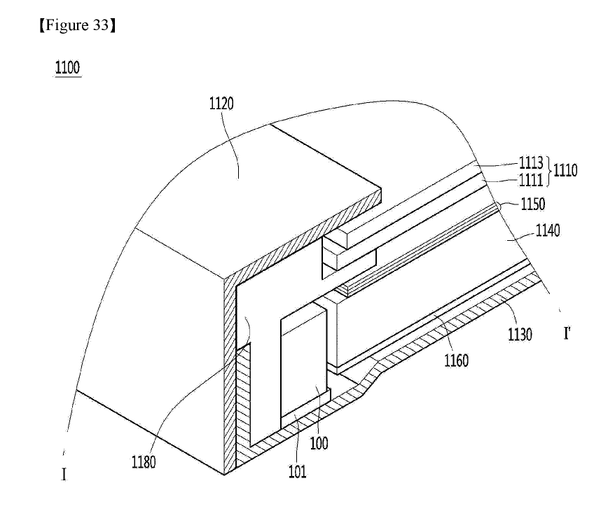

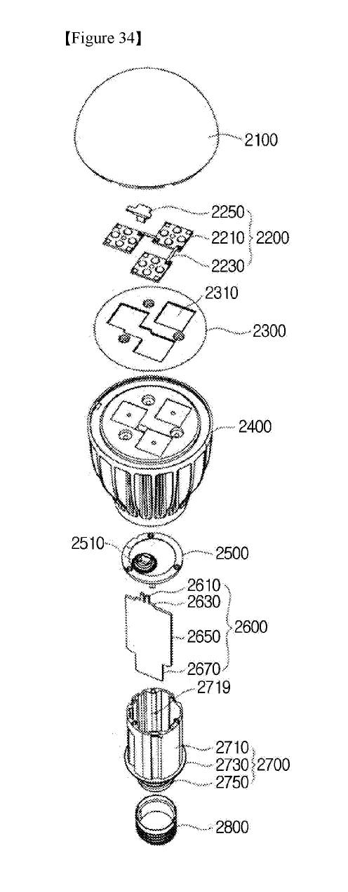

FIG. 33 is a perspective view showing the backlight unit of the embodiment.

FIG. 33, the liquid crystal display device 1100 of the embodiment comprises a liquid crystal display panel 1110, a backlight unit for providing light to the liquid crystal display panel 1110, a guide panel 1180, an upper cover 1120, and a bottom cover 1130.

The liquid crystal display panel 1110 may comprise an upper substrate 1113 and a lower substrate 1111. The liquid crystal display panel 1110 may comprise a liquid crystal layer (not shown) between the upper substrate 1113 and the lower substrate 1111 and may be connected to the lower substrate 1111 and a printed circuit board (not shown) that provides a signal, and may comprise a polarizing sheet.

In the liquid crystal display panel 1110, liquid crystal cells constituting pixel units are arranged in a matrix form, and liquid crystal cells control the light transmittance according to the image signal information transmitted from the driving PCB to display an image.

In the lower substrate 1111, a plurality of gate lines and a plurality of data lines may be arranged in a matrix, and a thin film transistor (TFT) may be disposed in a region where the gate lines and the data lines intersect.

The upper substrate 1113 may comprise a color filter, but is not limited thereto.

The upper cover 1120 may be disposed on the upper edge of the liquid crystal display panel 1110 and may be fastened to the guide panel 1180.

The bottom cover 1130 may have an open top surface. The bottom cover 1130 may be fastened to the guide panel 1180. For example, the bottom cover 1130 may be fastened to the guide panel 180 by a hook fastening structure, a screw fastening structure, and the like.

The guide panel 1180 may have a rectangular frame shape. The guide panel 1180 can support or accommodate the liquid crystal display panel 1110 and the backlight unit. To this end, the guide panel 1180 may comprise a step structure, a protrusion structure, and a groove structure.

The backlight unit may comprise a light guide plate 1140, a light source unit, optical sheets 1150, and a reflective sheet 1160.

The light source unit may comprise a circuit board 101 and a side view type light emitting device 100. The light emitting device 100 may be a light emitting device of the first to fifth embodiments of FIGS. 1 to 3.

The light emitting device 100 having a simplified structure can be disposed in the backlight unit of the embodiment to implement thinning and slimming. In addition, the backlight unit of the embodiment can improve the light efficiency incident on the light guide plate 1140 by resolving the light loss by the light emitting device 100 having a simplified structure. That is, the embodiment improves the incident light efficiency of the light guide plate 1140, thereby implementing a backlight unit of high brightness.

FIG. 34 is a perspective view showing the illumination device of the embodiment. As FIG. 34, the illumination device according to the embodiment comprises a cover 2100, a light source module 2200, a heat discharger 2400, a power supply unit 2600, an inner case 2700, a socket 2800. Further, the illumination device according to the embodiment may further comprise at least one of the member 2300 and the holder 2500. The light source module 2200 may comprise a light emitting device package according to an embodiment.

For example, the cover 2100 may have a shape of a bulb or a hemisphere, and may be provided in a shape whose inside is hollow and a part is opened. The cover 2100 may be optically coupled to the light source module 2200. For example, the cover 2100 may diffuse, scatter, or excite light provided from the light source module 2200. The cover 2100 may be a kind of optical member. The cover 2100 may be coupled to the heat discharging body 2400. The cover 2100 may have an engaging portion that engages with the heat discharging body 2400.

The inner surface of the cover 2100 may be coated with a milky white paint. The milky paint may comprise a diffusing agent for diffusing light. The surface roughness of the inner surface of the cover 2100 may be formed larger than the surface roughness of the outer surface of the cover 2100. This is for sufficiently diffusing and diffusing the light from the light source module 2200 and emitting it to the outside.

The cover 2100 may be made of glass, plastic, polypropylene (PP), polyethylene (PE), polycarbonate (PC), and the like. Here, polycarbonate is excellent in light resistance, and Heat resistance and strength. The cover 2100 may be transparent so that the light source module 2200 is visible from the outside, and may be opaque. The cover 2100 may be formed by blow molding.

The light source module 2200 may be disposed on one side of the heat discharging body 2400. Accordingly, the heat from the light source module 2200 is conducted to the heat discharging body 2400. The light source module 2200 may comprise a light source unit 2210, a connection plate 2230, and a connector 2250.

The member 2300 is disposed on the upper surface of the heat discharging body 2400 and has guide holes 2310 through which the plurality of light source portions 2210 and the connector 2250 are inserted. The guide hole 2310 corresponds to the substrate of the light source part 2210 and the connector 2250.

The surface of the member 2300 may be coated or coated with a light reflecting material. For example, the surface of the member 2300 may be coated or coated with a white paint. The member 2300 reflects the light reflected by the inner surface of the cover 2100 toward the cover 2100 in the direction toward the light source module 2200. Therefore, the light efficiency of the illumination device according to the embodiment can be improved.

The member 2300 may be made of an insulating material, for example. The connection plate 2230 of the light source module 2200 may comprise an electrically conductive material. Therefore, electrical contact may be made between the heat discharging body 2400 and the connecting plate 2230. The member 2300 may be formed of an insulating material to prevent an electrical short circuit between the connection plate 2230 and the heat discharging body 2400. The heat discharger 2400 receives heat from the light source module 2200 and heat from the power supply unit 2600 to dissipate heat.

The holder 2500 closes the receiving hole 2719 of the insulating portion 2710 of the inner case 2700. Therefore, the power supply unit 2600 housed in the insulating portion 2710 of the inner case 2700 is sealed. The holder 2500 has a guide protrusion 2510. The guide protrusion 2510 has a hole through which the protrusion 2610 of the power supply unit 2600 passes.

The power supply unit 2600 processes or converts an electrical signal provided from the outside and provides the electrical signal to the light source module 2200. The power supply unit 2600 is accommodated in the accommodation hole 2719 of the inner case 2700 and is sealed inside the inner case 2700 by the holder 2500. The power supply unit 2600 may comprise a protrusion 2610, a guide unit 2630, a base 2650, and an extension unit 2670.

The guide portion 2630 has a shape protruding outward from one side of the base 2650. The guide portion 2630 may be inserted into the holder 2500. A plurality of parts may be disposed on one side of the base 2650. The plurality of components comprise, for example, a DC converter for converting an AC power supplied from an external power source into a DC power source, a driving chip for controlling driving of the light source module 2200, an ESD (Electro Static discharge) protection device, and the like, but the present invention is not limited thereto.

The extending portion 2670 has a shape protruding outward from the other side of the base 2650. The extension portion 2670 is inserted into the connection portion 2750 of the inner case 2700 and receives an external electrical signal. For example, the extension portion 2670 may be provided to be equal to or smaller than the width of the connection portion 2750 of the inner case 2700. One end of each of the positive wire and the negative wire is electrically connected to the extension portion 2670 and the other end of the positive wire and the negative wire are electrically connected to the socket 2800.

The features, structures, effects and the like described in the embodiments are comprised in at least one embodiment and are not necessarily limited to one embodiment. Furthermore, the features, structures, effects and the like illustrated in the embodiments can be combined and modified by other persons skilled in the art to which the embodiments belong. Accordingly, the contents of such combinations and modifications should be interpreted as being comprised in the scope of the embodiments.

While the present invention has been particularly shown and described with reference to exemplary embodiments thereof, it is to be understood that the invention is not limited to the disclosed embodiments, but, on the contrary, it can be seen that the modification and application of branches are possible. For example, each component specifically shown in the embodiments can be modified and implemented. It is to be understood that the present invention may be embodied in many other specific forms without departing from the spirit or essential characteristics thereof

### INDUSTRIAL APPLICABILITY

The light emitting device package 110 according to the embodiment may be applied to not only the display device but also a lighting unit, a pointing device, a lamp, a streetlight, a vehicle lighting device, a vehicle display device, a smart watch, and the like, but is not limited thereto.

1. A light emitting device comprising;
a phosphor layer disposed on the light emitting structure; and
a first pad and a second pad electrically connected to the light emitting structure,
wherein the phosphor layer is disposed on a light emitting portion disposed on one side of the light emitting device,
wherein the light emitting structure comprises:
a first conductivity type semiconductor layer including a light extracting structure;
an active layer on the first conductivity type semiconductor laver; and
a second conductivity type semiconductor layer on the active layer,
wherein the light emitting structure comprises a first light emitting structure and a second light emitting structure electrically connected each other,
wherein a first portion of the first conductivity type semiconductor layer is exposed between the first light emitting structure and a second light emitting structure,
wherein the first pad is electrically connected to the exposed first portion of the first conductivity type semiconductor layer, and
wherein the second pad electrically connected to the second conductivity type semiconductor layer.

2. The light emitting device according to claim 1,
wherein the first conductivity type semiconductor layer is in direct contact with the phosphor layer.

3. The light emitting device according to claim 2, wherein the phosphor layer is in direct contact with the light extracting structure of the first conductivity type semiconductor layer.

4. The light emitting device according to claim 1, wherein the first and second pads are exposed on a rear surface of a light emitting device which is symmetrical with the light emitting portion.

5. The light emitting device according to claim 1, wherein the first and second pads are exposed on a rear surface of the light emitting device which is symmetrical with the light emitting portion, and an upper portion of the light emitting device which is symmetrical with the bottom portion.

6. The light emitting device according to claim 1, wherein the first and second pads are exposed on a side surface of the light emitting device that is symmetrical with the light emitting portion, an upper portion of the light emitting device that is symmetrical with the lower portion.

7. The light emitting device according to claim 4, wherein the first and second pads exposed on a rear surface of the light emitting device comprise a bended structure symmetrical to each other in a diagonal direction.

8. The light emitting device according to claim 2, further comprising:
a first electrode electrically connected to the first conductivity type semiconductor layer:
a second electrode electrically connected to the second conductivity type semiconductor layer; and
a first insulating layer surrounding the light emitting structure and the first and second electrodes,
wherein an edge of the first insulating layer is disposed in parallel with a light extracting structure of the first conductive type semiconductor layer, and
wherein the first insulating layer directly contacts the phosphor layer.

9. The light emitting device according to claim 8, wherein the first insulating layer comprises a first via hole exposing a part of the first electrode and at least one second via hole exposing a part of the second electrode,
further comprising a first connection electrode connected to one electrode; and a second connection electrode connected to the second electrode of the second via hole.

10. The light emitting device according to claim 9, wherein the first pad is disposed on the first connection electrode, the second pad is disposed on the second connection electrode, and
further comprising a second insulating layer surrounding the first insulation layer, the first and second connection electrodes and the first and second pads.

11. The light emitting device according to claim 9, wherein the first connection electrode is in-contact with the exposed first portion of the first conductivity type semiconductor layer,
the second connection electrode is in-contact with a second portion of the second conductivity type semiconductor layer of the second light emitting structure, and
wherein an area of the second portion is greater than that of the first portion.

12. The light emitting device according to claim 11, wherein the exposed first portion in-contact with the first connection electrode is positioned between the first pad and the second pad.

13. A light emitting device comprising;
a phosphor layer disposed on the light emitting structure including a first conductivity type semiconductor layer having a light extracting structure, an active layer on the first conductivity type semiconductor layer and a second conductivity type semiconductor layer on the active layer, a first pad and a second pad electrically connected to the light emitting structure;
a first electrode electrically connected to the first conductivity type semiconductor layer;
a second electrode electrically connected to the second conductivity type semiconductor layer; and
a third insulating layer surrounding the light emitting structure and the first and second electrodes,
wherein the phosphor layer is disposed on a light emitting portion disposed on one side of the light emitting device, and
wherein an edge of the third insulating layer is disposed lower than the active layer of the light emitting structure.

14. The light emitting device according to claim 13, wherein the light emitting structure comprises a first light emitting structure and a second light emitting structure electrically connected each other,
wherein a first portion of the first conductivity type semiconductor layer is exposed between the first light emitting structure and a second light emitting structure,
wherein the first pad is electrically connected to the exposed first portion of the first conductivity type semiconductor layer, and
wherein the second pad electrically connected to the second conductivity type semiconductor layer.

15. The light emitting device according to claim 14, wherein the third insulating layer comprises a first via hole exposing a part of the first electrode and at least one second via hole exposing a part of the second electrode,
further comprising a first connection electrode connected to one electrode; and a second connection electrode connected to the second electrode of the second via hole.

16. The light emitting device according to claim 15, wherein the first pad is disposed on the first connection electrode, the second pad is disposed on the second connection electrode, and
further comprising a second insulating layer surrounding the third insulation layer, the first and second connection electrodes and the first and second pads.

17. The light emitting device according to claim 16, wherein the first connection electrode is in-contact with the exposed first portion of the first conductivity type semiconductor layer,
the second connection electrode is in-contact with a second portion of the second conductivity type semiconductor layer of the second light emitting structure.

18. The light emitting device according to claim 17, wherein an area of the second portion is greater than that of the first portion.

19. The light emitting device according to claim 17, wherein the exposed first portion in-contact with the first connection electrode is positioned between the first pad and the second pad.

20. A light emitting device package including the light emitting device according to claim 1.
